(19) United States
(12) Patent Application Publication
(10) Pub. No.: US 2025/0267838 A1
(43) Pub. Date: Aug. 21, 2025

(54) METHOD OF MANUFACTURING SEMICONDUCTOR DEVICES

(71) Applicant: Samsung Electronics Co., Ltd., Suwon-si (KR)

(72) Inventors: Heejae Chae, Suwon-si (KR); Hongjun Lee, Suwon-si (KR); Yongkwan Kim, Suwon-si (KR); Huijung Kim, Suwon-si (KR); Hyunjin Lee, Suwon-si (KR)

(21) Appl. No.: 18/939,604

(22) Filed: Nov. 7, 2024

(30) Foreign Application Priority Data
Feb. 16, 2024 (KR) 10-2024-0022440

(51) Int. Cl. H10B 12/00

(52) U.S. Cl. CPC H10B 12/053; H10B 12/315; H10B 12/34

(57) ABSTRACT

A method of manufacturing a semiconductor device includes: forming an insulating layer on a substrate; forming mask patterns on the insulating layer, the mask patterns extending in a first horizontal direction and spaced apart from each other in a second horizontal direction intersecting the first horizontal direction; forming spacer layers on side surfaces of the mask patterns, wherein the spacer layers are spaced apart from each other in the second horizontal direction with each of the mask patterns interposed therebetween; forming spacer patterns spaced apart from each other in the first horizontal direction on the side surfaces of the mask patterns by patterning the spacer layers; forming mold patterns by etching the insulating layer using the mask patterns and the spacer patterns as an etching mask; and forming a device isolation trench defining semiconductor patterns by etching the substrate using the mold patterns as an etching mask.

### CROSS-REFERENCE TO RELATED APPLICATION(S)

This application claims priority to Korean Patent Application No. 10-2024-0022440, filed on Feb. 16, 2024 in the Korean Intellectual Property Office, the contents of which are incorporated herein by reference in its entirety.

### BACKGROUND

The present inventive concept relates to a method of manufacturing a semiconductor device.

As demand for high performance, high speed, and/or multifunctionality of semiconductor devices increases, a degree of integration of semiconductor devices is increasing. In manufacturing fine-patterned semiconductor devices, and in response to the trend toward high integration of semiconductor devices, it is important to implement patterns with fine widths or fine spacings.

### SUMMARY

An aspect of the present inventive concept is to provide a method of manufacturing a semiconductor device including forming spacer layers on side surfaces of mask patterns, forming spacer patterns by etching the spacer layers, and forming a semiconductor pattern on an upper surface of a substrate by an etching process using the mask patterns and the spacer patterns as an etching mask.

According to aspects of the present inventive concept, a method of manufacturing a semiconductor device may include: forming an insulating layer on a substrate; forming mask patterns on the insulating layer, the mask patterns extending in a first horizontal direction and spaced apart from each other in a second horizontal direction intersecting the first horizontal direction; forming spacer layers on side surfaces of the mask patterns, wherein the spacer layers are spaced apart from each other in the second horizontal direction with each of the mask patterns interposed therebetween; forming spacer patterns spaced apart from each other in the first horizontal direction on the side surfaces of the mask patterns by patterning the spacer layers; forming mold patterns by etching the insulating layer using the mask patterns and the spacer patterns as an etching mask; and forming a device isolation trench defining semiconductor patterns by etching the substrate using the mold patterns as an etching mask.

According to aspects of the present inventive concept, a method of manufacturing a semiconductor device may include: forming an insulating layer on a substrate; forming a mask pattern extending in a first horizontal direction on the insulating layer of the substrate; forming a first spacer layer and a second spacer layer formed on side surfaces of the mask pattern in a self-aligned manner, wherein the first spacer layer and the second spacer layer extend in the first horizontal direction along the side surfaces of the mask pattern and are spaced apart from each other in a second horizontal direction, intersecting the first horizontal direction with the mask pattern interposed therebetween; forming a first spacer pattern and a second spacer pattern on the side surfaces of the mask pattern by patterning the first spacer layer and the second spacer layer, wherein the first spacer pattern and the second spacer pattern are disposed symmetrically with respect to a center of the mask pattern; forming a mold pattern by etching the insulating layer using the mask pattern, the first spacer pattern, and the second spacer pattern as an etching mask; and forming a device isolation trench defining semiconductor patterns by etching the substrate using the mold pattern as an etching mask. Each of the semiconductor patterns may include a body portion extending in the first horizontal direction, and a first head portion and a second head portion respectively on side surfaces of opposite ends of the body portion. The body portion may correspond to the mask pattern, and each of the first head portion and the second head portion may correspond respectively to the first spacer pattern and the second spacer pattern.

According to aspects of the present inventive concept, a method of manufacturing a semiconductor device may include: forming semiconductor patterns including body portions, and first head portions and second head portions respectively disposed on side surfaces of opposite ends of the body portions; forming gate structures intersecting the body portions of the semiconductor patterns; forming bit line structures intersecting the gate structures; and forming landing pads electrically connected to the semiconductor patterns on the bit line structures. Forming the semiconductor patterns may include: forming an insulating layer on a substrate; forming mask patterns on the insulating layer, the mask patterns extending in a first horizontal direction and spaced apart from each other in a second horizontal direction intersecting the first horizontal direction; forming spacer layers on side surfaces of the mask patterns, wherein the spacer layers are spaced apart from each other in the second horizontal direction with each of the mask patterns interposed therebetween; forming spacer patterns spaced apart from each other in the first horizontal direction on the side surfaces of the mask patterns by patterning the spacer layers; forming mold patterns by etching the insulating layer using the mask patterns and the spacer patterns as an etching mask; and forming a device isolation trench defining the semiconductor patterns by etching the substrate using the mold patterns as an etching mask.

### BRIEF DESCRIPTION OF DRAWINGS

The above and other aspects, features, and advantages of the present disclosure will be more clearly understood from the following detailed description, taken in conjunction with the accompanying drawings:

FIG. 1A is a flow chart illustrating a method of manufacturing a semiconductor device according to an example embodiment;

FIG. 1B is a flow chart illustrating a method of forming a semiconductor pattern according to an example embodiment;

FIGS. 2A-12A and 2B-12B are plan views and vertical cross-sectional views shown according to a process sequence to illustrate a method of forming a semiconductor pattern according to an example embodiment;

FIG. 13 illustrates a semiconductor pattern according to an example embodiment;

FIGS. 14A, 14B, 15-20, 20A, and 20B are plan views and vertical cross-sectional views shown according to a process sequence to illustrate a method of manufacturing a semiconductor device according to an example embodiment; and

FIGS. 21A-28A and 21B-28B are plan views and vertical cross-sectional views shown according to a process sequence to illustrate a method of forming a semiconductor pattern according to an example embodiment.

### DETAILED DESCRIPTION

Hereinafter, example embodiments of the present inventive concept will be described with reference to the attached drawings.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

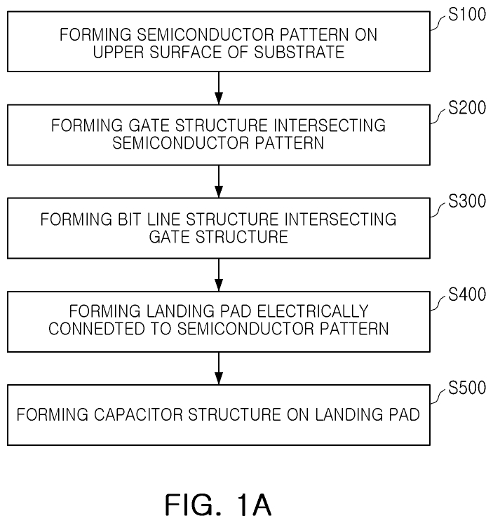

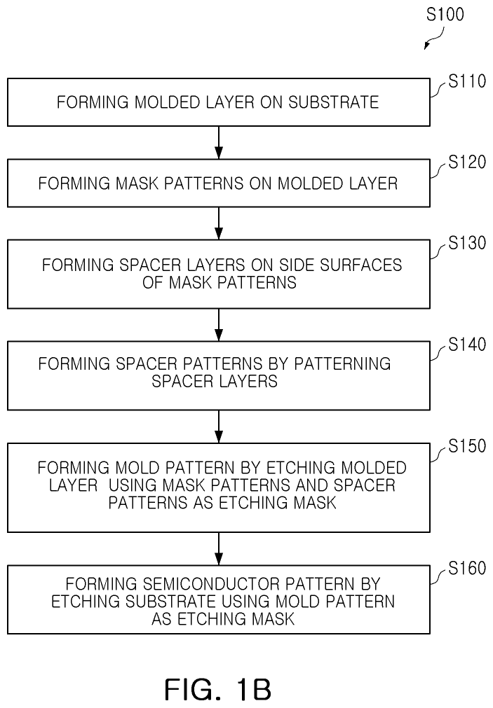

FIG. 1A is a flow chart illustrating a method of manufacturing a semiconductor device according to an example embodiment. FIG. 1B is a flow chart illustrating a method of forming a semiconductor pattern according to an example embodiment.

Referring to FIG. 1A, the method of manufacturing a semiconductor device may include forming a semiconductor pattern on an upper surface of a substrate (S100), forming a gate structure intersecting (e.g., crossing) the semiconductor pattern (S200), forming a bit line structure intersecting (e.g., crossing) the gate structure (S300), forming a landing pad electrically connected to the semiconductor pattern (S400), and forming a capacitor structure on the landing pad (S500). A semiconductor device may be, for example, a semiconductor chip including an integrated circuit formed on a die from a wafer, or may be a semiconductor package including such a chip.

Referring to FIG. 1B, the method of forming a semiconductor pattern (S100) may include forming a molded layer on a substrate (S110), forming mask patterns on the molded layer (S120), forming spacer layers on side surfaces of the mask patterns (S130), forming spacer patterns by patterning the spacer layers (S140), forming a mold pattern by etching the molded layer using the mask patterns and the spacer patterns as an etching mask (S150), and forming a semiconductor pattern by etching the substrate using the mold pattern as an etching mask (S160).

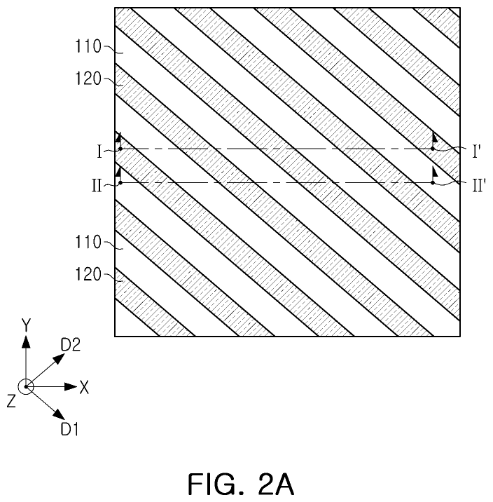

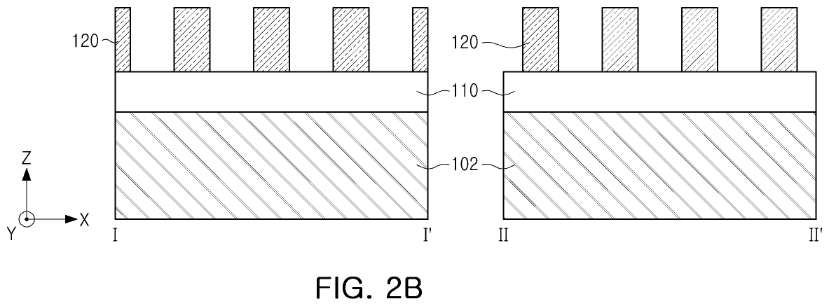

FIGS. 2A to 12B are plan views and vertical cross-sectional views shown according to a process sequence to illustrate a method of forming a semiconductor pattern according to an example embodiment. Specifically, FIGS. 2A, 3A, 4A, 5A, 6A, 7A, 8A, 9A, 10A, 11A, and 12A are plan views, and FIGS. 2B, 3B, 4B, 5B, 6B, 7B, 8B, 9B, 10B, 11B, and 12B are vertical cross-sectional views taken along lines I-I′ and II-II′ of FIGS. 2A, 3A, 4A, 5A, 6A, 7A, 8A, 9A, 10A, 11A, and 12A, respectively.

Referring to FIGS. 1B, 2A, and 2B, an insulating layer such as molded layer 110 may be formed on a substrate 102 (S110). The molded layer 110 may include silicon oxide. The substrate 102 may be a semiconductor substrate such as, for example, a silicon substrate, or may be a silicon-on-insulator substrate. The molded layer 110 may be formed by stacking a silicon oxide layer on the substrate 102 or by oxidizing an upper surface of the substrate 102.

Mask patterns 120 may be formed on the molded layer 110 (S120). The mask patterns 120 may be formed by forming a mask material layer on the molded layer 110, and patterning the mask material layer. The mask patterns 120 may extend in a DI direction, and may be spaced apart from each other in a D2 direction. The mask patterns 120 may include a material having etch selectivity with respect to that of the molded layer 110. In an example embodiment, the mask patterns 120 may include polysilicon.

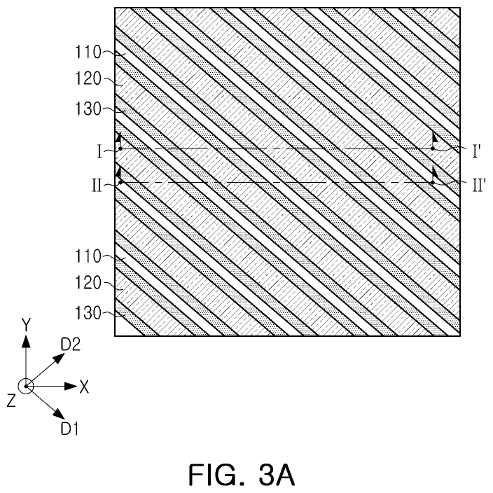

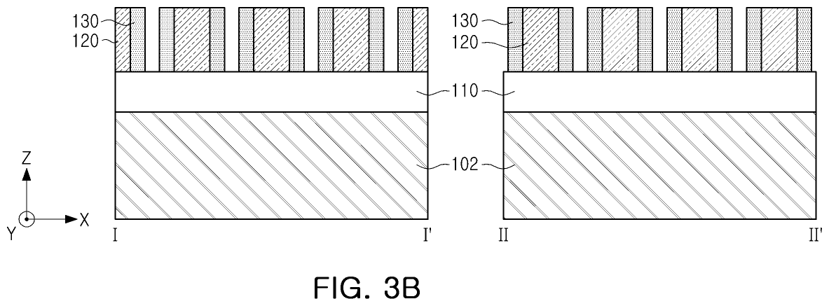

Referring to FIGS. 1B, 3A, and 3B, spacer layers 130 may be formed on side surfaces of the mask patterns 120 (S130). In an example embodiment, the spacer layers 130 may be formed on the side surfaces, e.g., sidewalls, of the mask patterns 120 in a self-aligned manner. For example, the spacer layers 130 may be formed by depositing a spacer material layer to cover the molded layer 110 and the mask patterns 120 and anisotropically etching the spacer material layer to remove portions on top of the mask patterns 120 and on part of a surface of the molded layer 110.

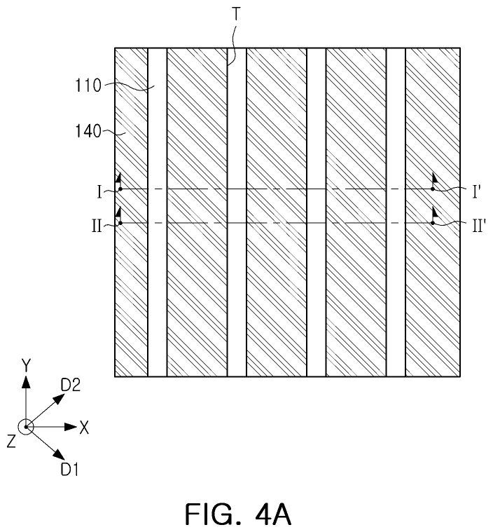

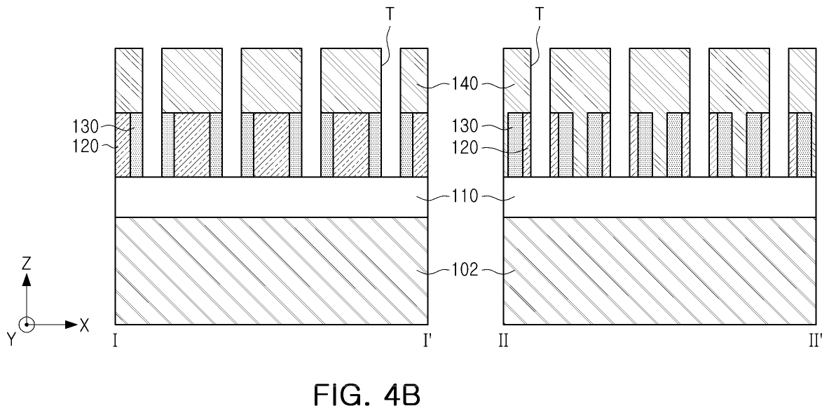

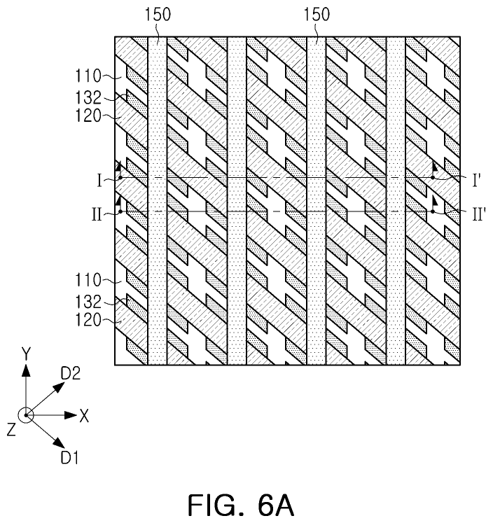

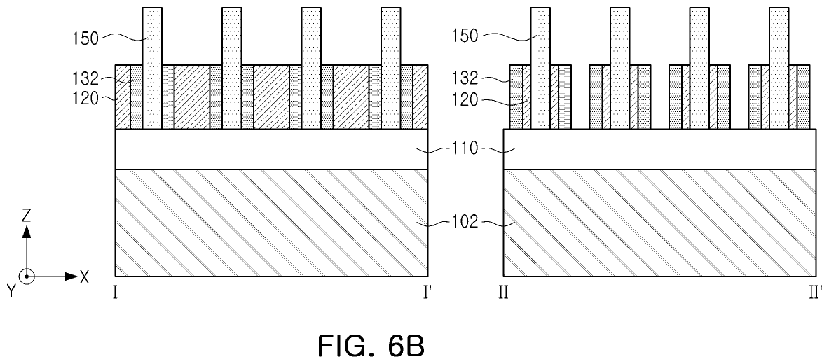

Referring to FIGS. 4A and 4B, a first hard mask layer 140 may be formed. The first hard mask layer 140 may cover the molded layer 110, the mask patterns 120, and the spacer layers 130. After the first hard mask layer 140 is formed, trenches T may be formed in the first hard mask layer 140 through an anisotropic etching process. The trenches T may extend in the Y-direction and may be spaced apart from each other in the X-direction. In the etching process, the mask patterns 120 and spacer layers 130 may be partially etched, and an upper surface of the molded layer 110 may be exposed. The etched mask patterns 120 may extend in the DI direction, and may be spaced apart from each other in the DI direction, X-direction, and Y-direction (see FIG. 6A). The first hard mask layer 140 may include spin on hardmask (SOH).

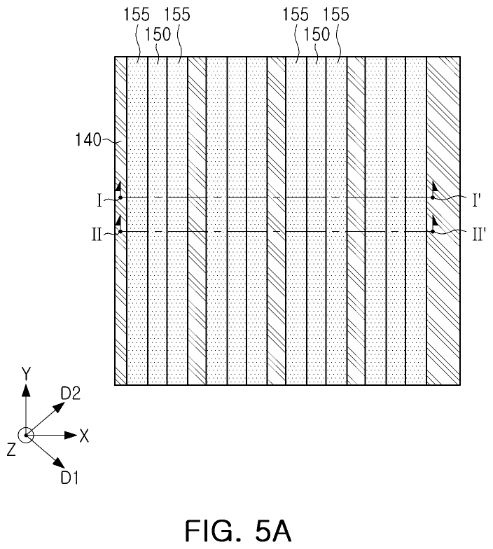

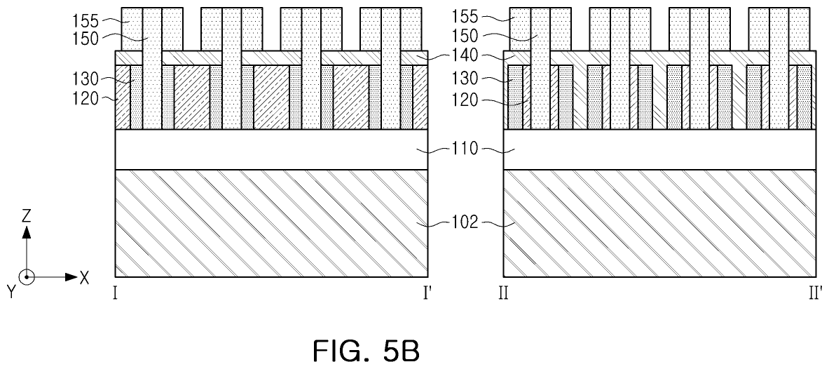

Referring to FIGS. 5A and 5B, sacrificial patterns 150 may be formed to fill the trenches T and intersect the mask patterns 120 and spacer layers 130. The sacrificial patterns 150 may extend vertically and contact side surfaces, e.g., sidewalls, of the mask patterns 120 and the spacer layers 130. The sacrificial patterns 150 may extend in the Y-direction and may be spaced apart from each other in the X-direction. The sacrificial patterns 150 may include silicon oxide.

After the sacrificial patterns 150 are formed, an upper portion of the first hard mask layer 140 may be etched and side surfaces of the sacrificial patterns 150 may be exposed. Thereafter, sacrificial spacers 155 may be formed on the side surfaces of the sacrificial patterns 150 and the upper surface of the first hard mask layer 140. The sacrificial spacers 155 may be formed on the side surfaces of the sacrificial patterns 150 in a self-aligned manner. For example, the sacrificial spacers 155 may be formed by depositing a sacrificial material to cover the first hard mask layer 140 and the sacrificial patterns 150 and then anisotropically etching the sacrificial material. The sacrificial spacers 155 may extend in the Y-direction along the side surfaces of the sacrificial patterns 150 and may be spaced apart from each other in the X-direction. The sacrificial spacers 155 may include silicon oxide.

Referring to FIGS. 1B, 6A, and 6B, the spacer layers 130 may be patterned to form spacer patterns 132 (S140). Forming the spacer patterns 132 (S140) may include antisotropically etching the spacer layers 130 and the first hard mask layer 140 using the sacrificial patterns 150 and the sacrificial spacers 155 as an etching mask. The spacer patterns 132 may be disposed on side surfaces of the mask patterns 120 in the DI direction. For example, four spacer patterns 132 may be disposed on the side surface of each mask patterns 120. After the spacer patterns 132 are formed, the first hard mask layer 140 may be removed.

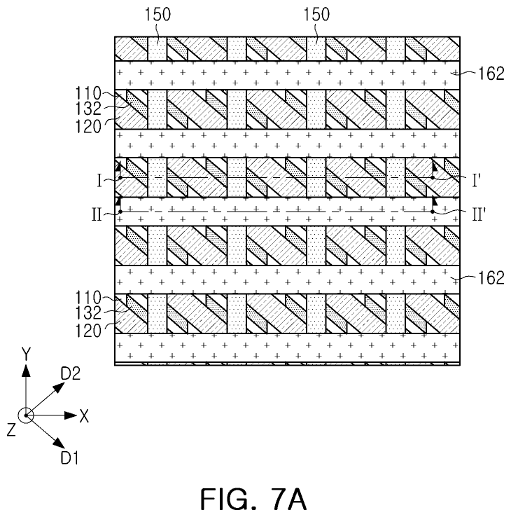

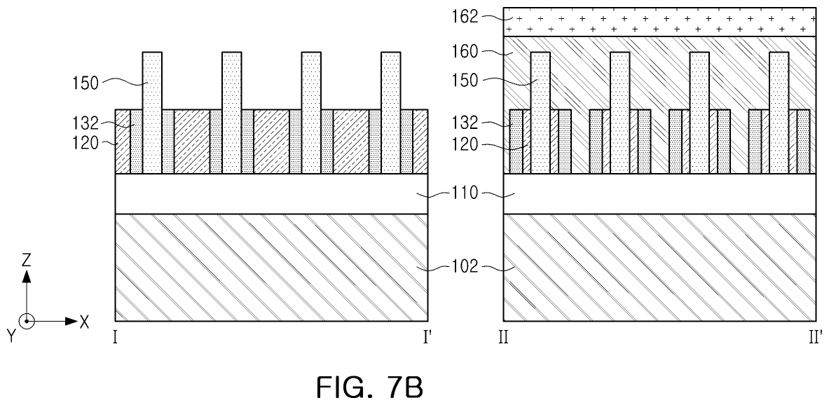

Referring to FIGS. 7A and 7B, a second hard mask layer 160 and an anti-reflection layer 162 may be formed to cover the mask patterns 120 and spacer patterns 132. The second hard mask layer 160 and the anti-reflection layer 162 may extend in the X-direction and may be spaced apart from each other in the Y-direction. The second hard mask layer 160 and the anti-reflection layer 162 may partially expose the spacer patterns 132 and sacrificial patterns 150. The second hard mask layer 160 may include SOH, and the anti-reflection layer 162 may include silicon nitride, silicon oxynitride, or a combination thereof.

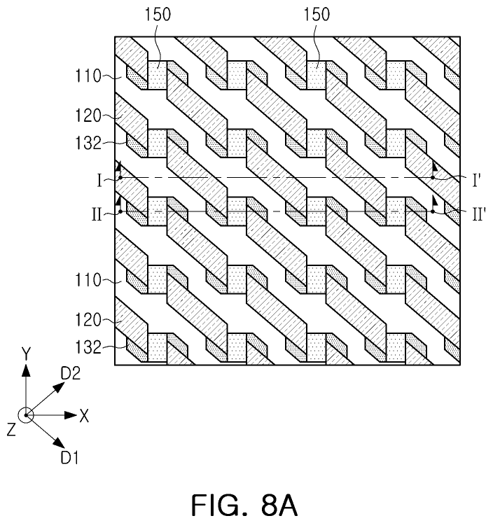

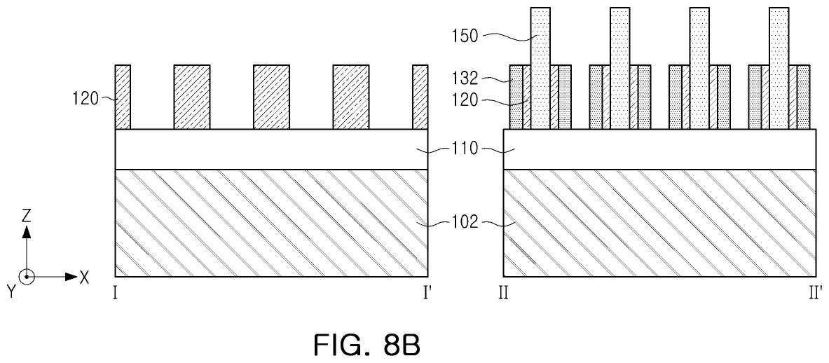

Referring to FIGS. 8A and 8B, the spacer patterns 132 and sacrificial patterns 150 may be etched using the second hard mask layer 160 as an etching mask. A portion of the spacer patterns 132 may be removed, and the remaining spacer patterns 132 may be partially etched. For example, two spacer patterns 132 may be disposed on the side surface of each mask pattern 120. The respective spacer patterns 132 may overlap ends of the corresponding mask patterns 120 in the Y-direction.

The etched sacrificial patterns 150 may be spaced apart from each other in the X and Y directions. The second hard mask layer 160 and anti-reflection layer 162 may be removed.

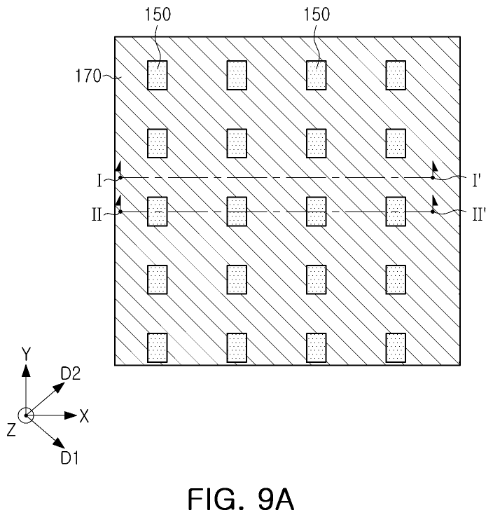

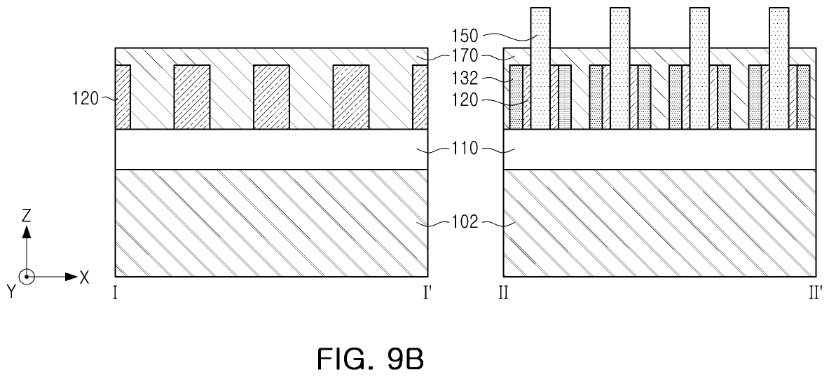

Referring to FIGS. 9A and 9B, after a third hard mask layer 170 is formed to cover the mask patterns 120, the spacer patterns 132, and the sacrificial patterns 150, an upper portion of the third hard mask layer 170 may be etched to expose the sacrificial patterns 150. The third hard mask layer 170 may include SOH.

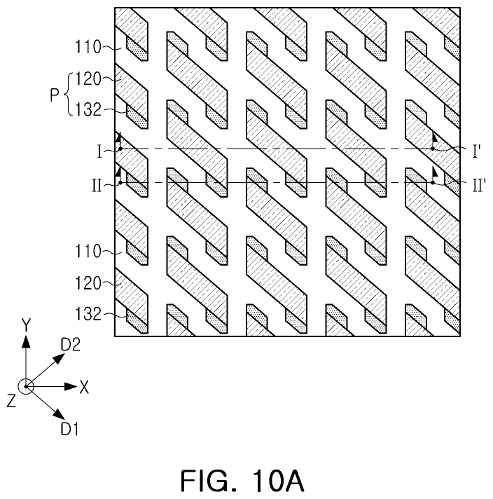

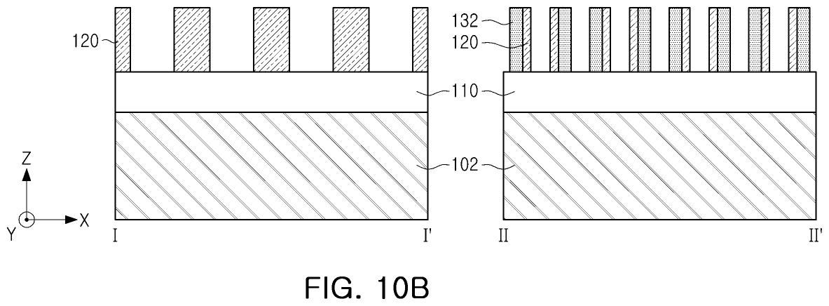

Referring to FIGS. 10A and 10B, the exposed sacrificial patterns 150 may be selectively removed. The third hard mask layer 170 may be removed. The spacer patterns 132 may be disposed symmetrically with respect to a center of the corresponding mask patterns 120. The mask patterns 120 and the spacer patterns 132 may form a preliminary pattern P. Each preliminary pattern P may include a spacer pattern on a first side surface of one mask pattern and a spacer pattern on a second side surface opposite to the first side surface. The preliminary pattern P may be disposed at a position corresponding to a semiconductor pattern 106, which will be described later.

As shown in FIGS. 5A and 5B, a width of the mask patterns 120 in the X-direction may be defined by the sacrificial patterns 150. In addition, as shown in FIGS. 6A and 6B, a width of the spacer patterns 132 in the X-direction may be defined by the sacrificial spacers 155, formed on side surfaces of the sacrificial patterns 150 in a self-aligned manner. Since the spacer patterns 132 are formed by the self-aligned sacrificial spacers 155, process deviations variations of the preliminary patterns P may be reduced compared to when the mask patterns 120 and the spacer patterns 132 are patterned through separate exposure processes.

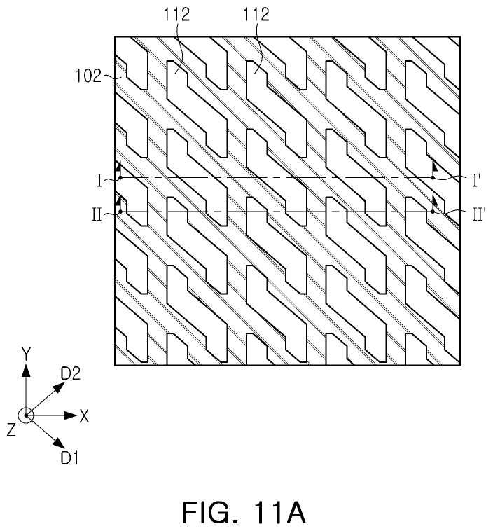

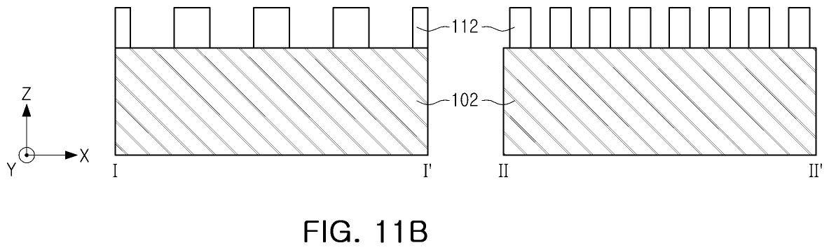

Referring to FIGS. 11A and 11B, the molded layer 110 may be etched using the mask patterns 120 and the spacer patterns 132 as an etching mask to form mold patterns 112 (S150).

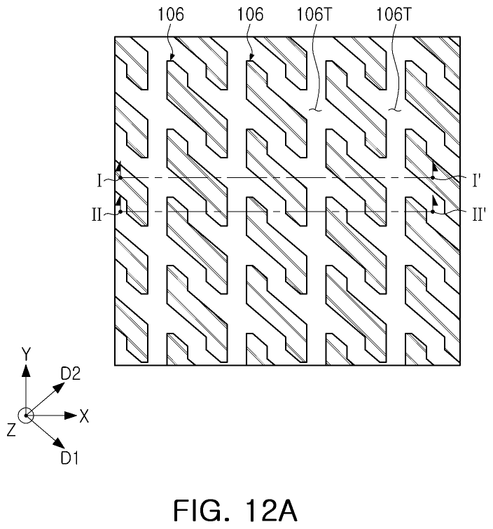

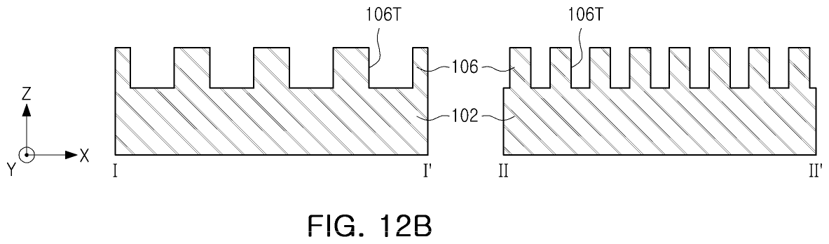

Referring to FIGS. 12A and 12B, the substrate 102 may be etched using the mold pattern 112 as an etching mask to form semiconductor patterns 106 and device isolation trenches 106T (S160). The device isolation trenches 106T may be formed on the upper surface of the substrate 102 and may define semiconductor patterns 106.

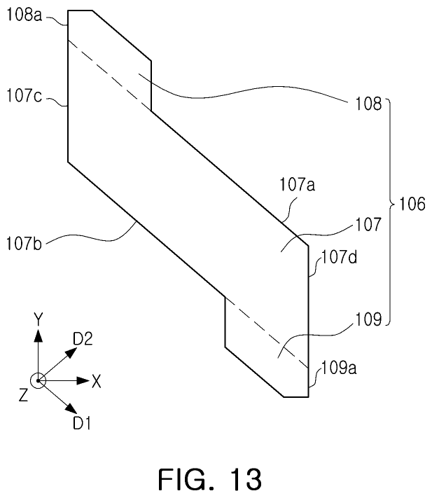

FIG. 13 illustrates a semiconductor pattern according to an example embodiment. For example, FIG. 13 is a partially enlarged view of FIG. 12A.

Referring to FIG. 13, the semiconductor pattern 106 may include a body portion 107 and a first head portion 108 and a second head portion 109 on side surfaces of both (e.g., opposite) ends of the body portion 107. For example, the first head portion 108 and the second head portion 109 may protrude in the Y direction from both (e.g., opposite) ends of the body portion 107 in the DI direction. The first head portion 108 and the second head portion 109 may be disposed symmetrically (e.g., radially symmetrically) with respect to the center of the body portion 107.

The body portion 107 may extend lengthwise in a D1 direction to have opposite ends in the D1 direction. Each of the first head portion 108 and the second head portion 109 may overlap, in the Y direction, a respective end of the body portion 107. For example, the body portion 107 may include a first side surface 107a perpendicular to a D2 direction and a second side surface 107b opposite to the first side surface 107a, and each of the first head portions 108 may extend lengthwise in the D1 direction on the first side surface 107a and the second side surface 107b of the body portion 107. An item, layer, or portion of an item or layer described as extending “lengthwise” in a particular direction has a length in the particular direction and a width perpendicular to that direction, where the length is greater than the width. Each of the first head portion 108 and the second head portion 109 may include a side surface coplanar with the body portion 107. For example, the body portion 107 may include a third side surface 107c, perpendicular to the X direction and a fourth side surface 107d opposite to the third side surface 107c. The side surface 108a of the first head portion 108 may be coplanar with the third side surface 107c of the body portion 107, and the side surface 109a of the second head portion 109 may be coplanar with the fourth side surface 107d of the body portion 107.

The body portion 107, the first head portion 108, and the second head portion 109 may correspond to the mask patterns 120 and the spacer patterns 132 shown in FIG. 10A, respectively. For example, each of the body portions 107 may be positioned in the same position (e.g., same horizontal position), from a plan view, as a corresponding one of the mask patterns 120. Each of the first head portions 108 and the second head portions 109 may be positioned in the same position (e.g., same horizontal position), from a plan view, as a corresponding one of the spacer patterns 132.

When the body portion 107, the first head portion 108, and the second head portion 109 are formed by patterning masks in different layers through an exposure process, the exposure process is performed multiple times, so that process deviations may increase. However, according to example embodiments of the present disclosure, as shown in FIG. 3B, the mask patterns 120 and the spacer layer 130 may be formed at the same vertical level and a preliminary pattern may be formed at the same vertical level as shown in FIG. 10B. Since the spacer layer 130 is formed on the side surface of the mask patterns 120 in a self-aligned manner, process variations in the positions and sizes of the spacer layers 130 can be reduced. In addition, as shown in FIGS. 5B and 6B, the sacrificial spacers 155 may be formed on the side surfaces of the sacrificial patterns 150 in a self-aligned manner, and the spacer patterns 132 may be formed by patterning the spacer layer 130 using the sacrificial patterns 150 and the sacrificial spacers 155 as an etching mask. Accordingly, process variations in the position and size of the spacer patterns 132 may be reduced. Therefore, defects in the semiconductor pattern 106 may be reduced. Here, the semiconductor pattern 106 may be referred to as an ‘active region’. The semiconductor pattern 106 may correspond to an active region 6a, which will be described later.

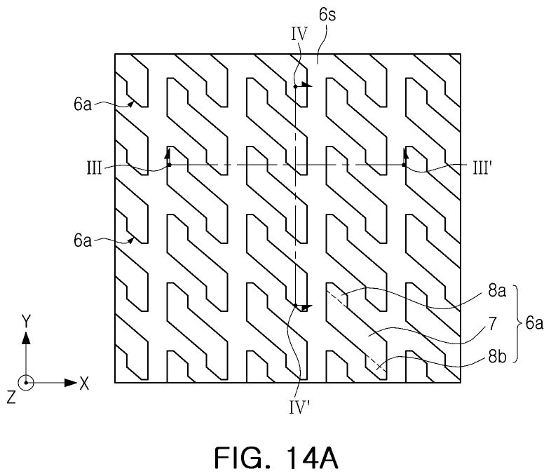

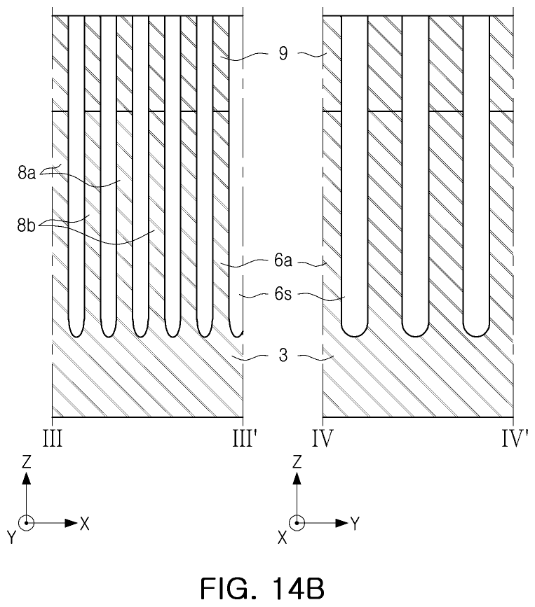

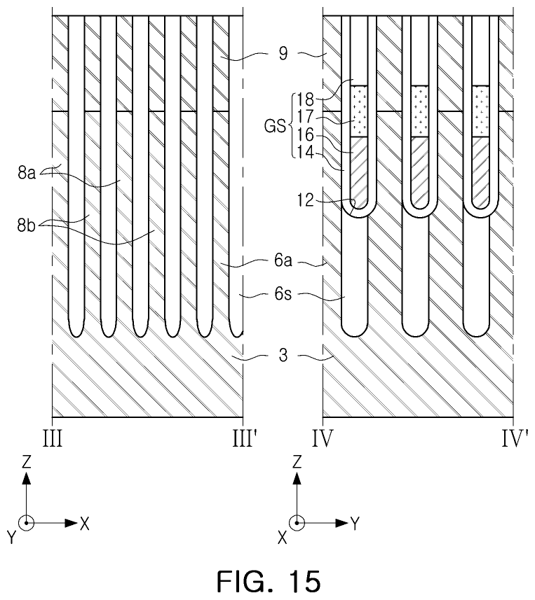

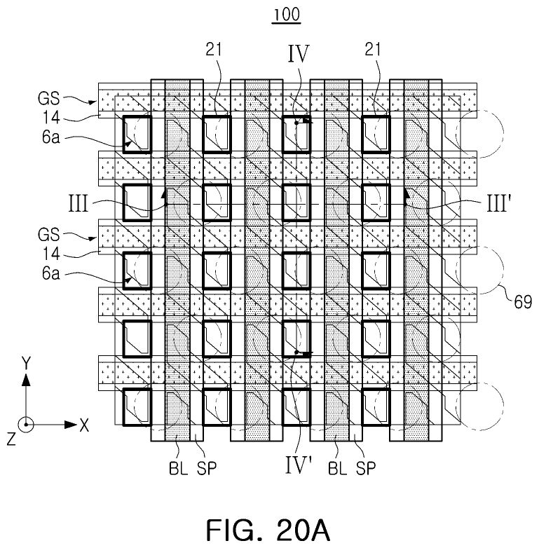

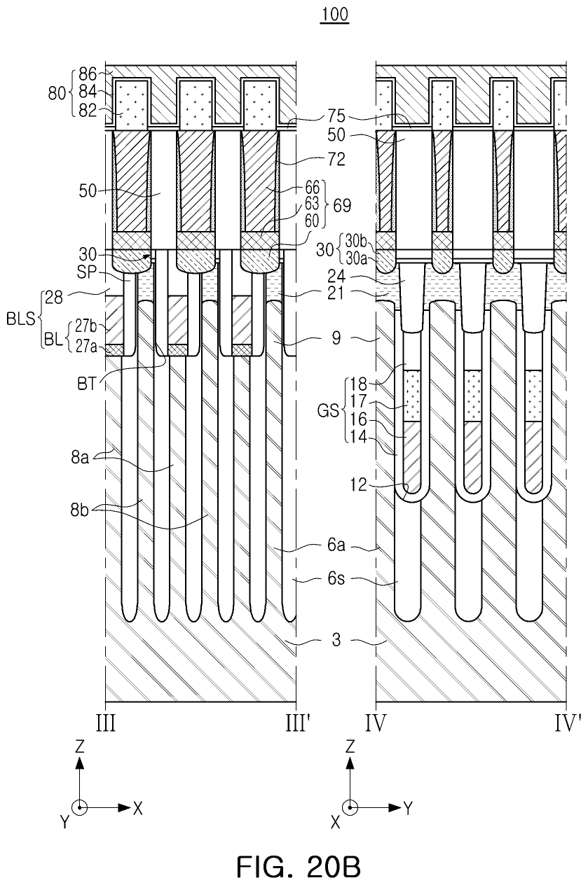

FIGS. 14A to 20B are plan views and vertical cross-sectional views shown according to a process sequence to illustrate a method of manufacturing a semiconductor device according to an example embodiment. Specifically, FIG. 14A is a plan view corresponding to FIG. 12A, and FIG. 14B is a vertical cross-sectional view taken along lines III-III′ and IV-IV′ of FIG. 14A. FIGS. 15 to 19 are vertical cross-sectional views corresponding to FIG. 14B. FIG. 20A is a plan view of a semiconductor device according to an example embodiment, and FIG. 20B is a vertical cross-sectional view taken along lines III-III′ and IV-IV′ shown in FIG. 20A.

Referring to FIGS. 1A, 14A, and 14B, active regions 6a and device isolation layers 6s may be formed on an upper surface of a substrate 3 (S100). The substrate 3 and the active regions 6a may correspond to the substrate 102 and the semiconductor patterns 106 shown in FIGS. 12A and 12B. A method of forming the active regions 6a may be the same or similar to the method of forming the semiconductor pattern 106 described with reference to FIGS. 2A to 12B.

The substrate 3 may include a semiconductor material, such as a group IV semiconductor, a group III-V compound semiconductor, or a group II-VI compound semiconductor. For example, the group IV semiconductor may include silicon, germanium, or silicon-germanium. The substrate 3 may be a substrate including a silicon substrate, a silicon on insulator (SOI) substrate, a germanium substrate, a germanium on insulator (GOI) substrate, a silicon-germanium substrate, or an epitaxial layer.

The active regions 6a may extend in a horizontal direction between the X and Y directions and may have an s-shape, for example. However, the active region 6a disclosed in this specification is exemplary, and the active regions 6a having various shapes may be implemented. When viewed in plan view, the active region 6a may include a body portion 7 and a first head portion 8a and a second head portion 8b disposed at opposite ends of the body portion 7. The body portion 7, the first head portion 8a, and the second head portion 8b may correspond to the body portion 107, the first head portion 108, and the second head portion 109 shown in FIG. 13. The active regions 6a may be spaced apart from each other in the X and Y directions. For example, the body portions 7 of the active regions 6a may be spaced apart in a lattice structure with regular intervals in the X-and Y-directions, respectively.

The device isolation layer 6s may be formed by removing a portion of an upper surface of the substrate 3, filling a space in which the substrate 3 was removed with an insulating material, and planarizing the insulating material. The device isolation layer 6s may be comprised of a single layer or multiple layers. In an example embodiment, a depth of the device isolation layer 6s may not be constant. The device isolation layer 6s may define active regions 6a. For example, the active regions 6a may correspond to a portion of the upper surface of the substrate 3 surrounded by the device isolation layer 6s.

The active region 6a may include impurity regions 9 extending from the upper surface of the substrate 3 to a predetermined depth. The impurity regions 9 may serve as source/drain regions of a transistor. For example, the impurity region 9 disposed in the first head portion 8a may correspond to the source region, and the impurity region 9 disposed in the second head portion 8b may correspond to the drain region. The source region and the drain region may be formed by doping or ion implantation of substantially the same impurities, and may be referred to interchangeably depending on the circuit configuration of the transistor. The impurity regions 9 may include impurities having a conductivity type opposite to that of the substrate 3. For example, the substrate 3 may include p-type impurities, and the impurity regions 9 may include n-type impurities.

In an example embodiment, impurity regions 9 may be formed by injecting impurities into the substrate 3 before the device isolation layer 6s is formed. However, depending on example embodiments, the impurity regions 9 may also be formed after the device isolation layer 6s is formed or in another process step.

Referring to FIGS. 1A and 15, a gate structure GS intersecting the semiconductor pattern may be formed (S200). Gate trenches 12 may be formed by anisotropically etching the substrate 3. The gate trenches 12 may extend in the X-direction and may cross the active region 6a and the device isolation layer 6s. A gate structure GS may be formed by forming a gate dielectric layer 14, a first gate electrode 16, a second gate electrode 17, and a gate capping layer 18 within the gate trench 12. A gate dielectric layer 14 may be formed by performing an oxidation process or a deposition process within the gate trench 12, and the gate dielectric layer 14 may be formed conformally on an inner wall of the gate trench 12.

The first gate electrode 16 may be formed by forming a conductive material on the gate dielectric layer 14, and then recessing the conductive material. The first gate electrode 16 may include a metal material such as tungsten (W). A second gate electrode 17 may be formed by depositing a semiconductor material including impurities on the first gate electrode 16. The semiconductor material may include, for example, polycrystalline silicon, and the impurities may include n-type impurities such as phosphorus (P) or arsenic (As).

The gate capping layer 18 may be formed by forming an insulating material on the second gate electrode 17 to fill the gate trench 12 and then performing a planarization process.

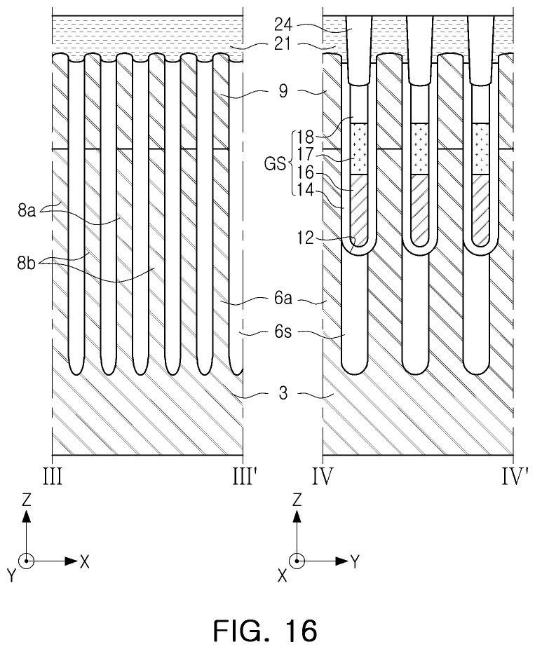

Each active region 6a may vertically overlap a corresponding one of the gate structures GS. For example, when viewed in plan view, the gate trenches 12 may vertically overlap body portions 7 of the active regions 6a and extend in the X-direction. The gate structures GS may be spaced apart from each other in the Y-direction. A first head portion 8a and a second head portion 8b of the active region 6a may not vertically overlap the gate structure GS. Referring to FIG. 16, the gate dielectric layer 14 and the device isolation layer 6s of the gate structure GS may be partially etched, to expose side surfaces of upper portions of the active regions 6a. A pad pattern 21 covering the active regions 6a and the gate structure GS may be formed. An insulating structure 24 vertically penetrating the pad pattern 21 may be formed. The insulating structure 24 may vertically overlap the gate structure GS, and may contact an upper surface of the gate capping layer 18. The pad patterns 21 may be alternately disposed with the insulating structures 24 in the Y-direction.

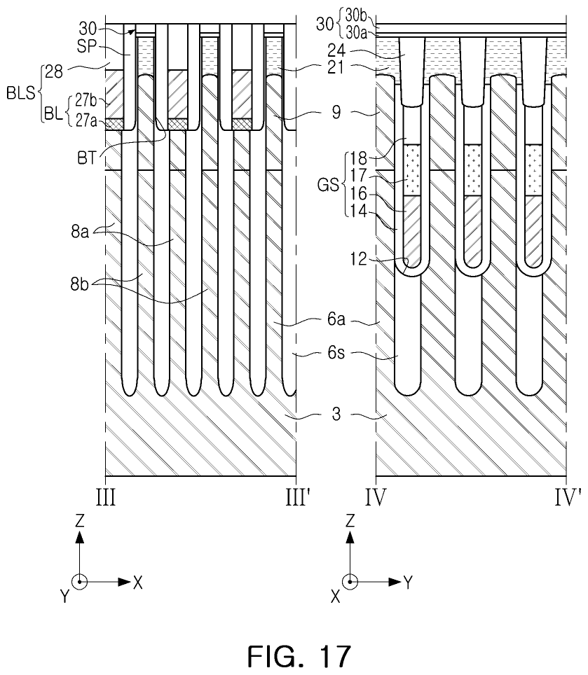

Referring to FIGS. 1A and 17, a buffer layer 30 may be formed on the pad pattern 21 and the insulating structure 24. The buffer layer 30 may include a first layer 30a and a second layer 30b on the first layer 30a. The first layer 30a may include silicon oxide, and the second layer 30b may include silicon nitride.

A bit line structure BLS intersecting the gate structure GS may be formed (S300). The bit line structure BLS may vertically overlap the first head portions 8a of the active regions 6a.

First, a bit line trench BT vertically penetrating the buffer layer 30 and the pad pattern 21 and exposing the active regions 61 may be formed. The bit line trenches BT may extend in the Y-direction, and may be spaced apart from each other in the X-direction. When forming the bit line trench BT, upper portions of the active region 6a and the device isolation layer 6s may be partially etched. For example, the bit line trench BT may expose the side surface of the upper portion of the device isolation layer 6s, and the upper surface of the first head portion 8a of the active region 6a. The first head portion 8a of the active region 6a may be exposed by the bit line trench BT, but the second head portion 8b may not be exposed by the bit line trench BT.

A spacer structure SP and a bit line structure BLS may be formed inside the bit line trench BT. The spacer structure SP may be formed by depositing an insulating material to cover an inner wall of the bit line trench BT, the pad pattern, and the buffer layer 30, and performing an anisotropic etching process to etch the insulating material. The spacer structure SP may cover a side surface of the bit line trench BT, a side surface of the pad pattern 21, and a side surface of the buffer layer 30, and may not cover the active region 6a. The spacer structure SP may be composed of a single layer or a plurality of layers. The spacer structure SP may extend in the Y-direction along the bit line trench BT.

After the spacer structure SP is formed, a bit line structure BLS may be formed by depositing a first conductive layer 27a, a second conductive layer 27b, and a bit line capping layer 28 within the bit line trench BT. Each of the first conductive layer 27a and the second conductive layer 27b may include a conductive material, and may form a bit line BL. The first conductive layer 27a may include a metal-semiconductor compound. For example, the metal-semiconductor compound may be a layer in which a portion of the active region 6a is silicided. For example, the metal-semiconductor compound may include cobalt silicide (CoSi), titanium silicide (TiSi), nickel silicide (NiSi), tungsten silicide (WSi), or other metal silicide. The second conductive layer 27b may include a metal material such as titanium (Ti), tantalum (Ta), tungsten (W), and aluminum (Al). The number, type of material, and/or stacking order of conductive patterns forming the bit line BL may vary depending on example embodiments.

The bit line capping layer 28 may be disposed on the second conductive layer 27b, and may completely fill the bit line trench BT. After the bit line capping layer 28 is formed, an etch-back process or a planarization process may be performed. Upper surfaces of the bit line capping layer 28, the spacer structure SP, and the buffer layer 30 may be coplanar.

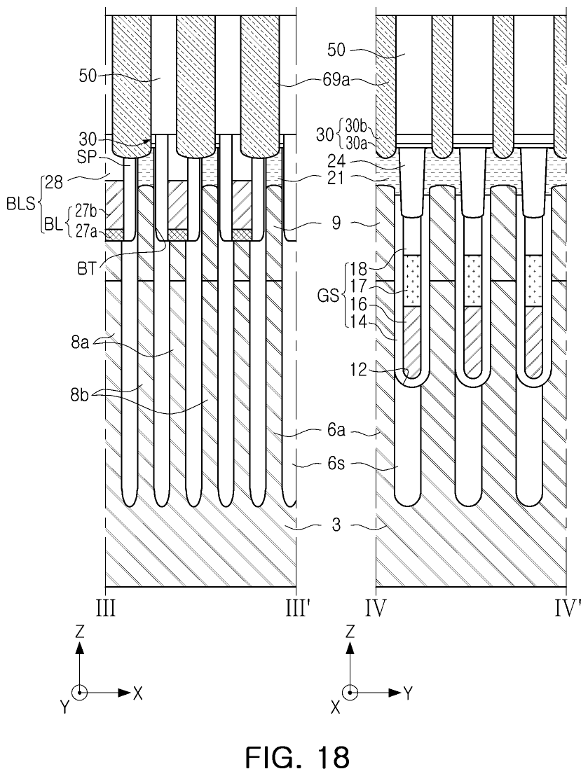

Referring to FIG. 18, an interlayer insulating layer 50 may be formed on the buffer layer 30 and the bit line structure BLS. A contact material layer 69a vertically penetrating the interlayer insulating layer 50 and in contact with the pad pattern 21 may be formed. An upper surface of the contact material layer 69a may be coplanar with an upper surface of the interlayer insulating layer 50. The contact material layer 69a may include polysilicon.

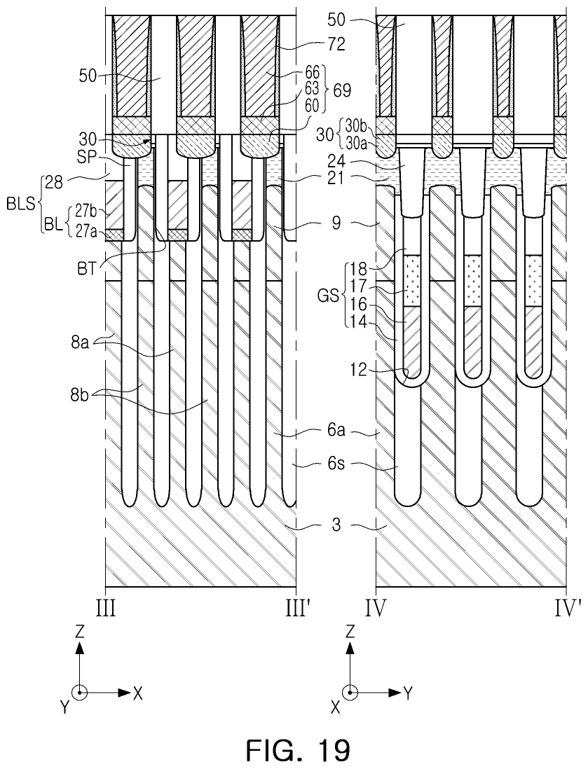

Referring to FIGS. 1A and 19, a landing pad 69 electrically connected to the semiconductor pattern may be formed (S400). A lower conductive layer 60 may be formed by etching the contact material layer 69a, and a middle conductive layer 63 and an upper conductive layer 66 may be formed on the lower conductive layer 60. The lower conductive layer 60, the middle conductive layer 63, and the upper conductive layer 66 may form a landing pad 69. In an example embodiment, a spacer 72 may be formed on a side surface of the interlayer insulating layer 50 before the upper conductive layer 66 is formed. The middle conductive layer 63 may be formed by siliciding the lower conductive layer 60, and the upper conductive layer 66 may include a metal material. The landing pad 69 may be in contact with the pad pattern 21, and may be electrically connected to the active area 6a through the pad pattern 21. The landing pad 69 may vertically overlap the second head portions 8b of the active regions 6a.

Referring to FIGS. 1A, 20A, and 20B, the semiconductor device 100 may be manufactured by forming a capacitor structure 80 on the landing pad 69 (S500).

First, an etch stop layer 72 may be formed on the interlayer insulating layer 50 and the landing pad 69. A lower electrode 82 penetrating the etch stop layer 75 and connected to the landing pad 69 may be formed. Thereafter, a capacitor dielectric layer 84 on the lower electrode 82, and an upper electrode 86 on the capacitor dielectric layer 84 may be formed.

The lower electrode 82 and the upper electrode 86 may include, for example, at least one of polycrystalline silicon, titanium nitride (TiN), tungsten (W), titanium (Ti), ruthenium (Ru), and tungsten nitride (WN). For example, the capacitor dielectric layer 84 may include at least one of high dielectric constant materials such as zirconium oxide (ZrO₂), aluminum oxide (Al₂O₃), and hafnium oxide (Hf₂O₃).

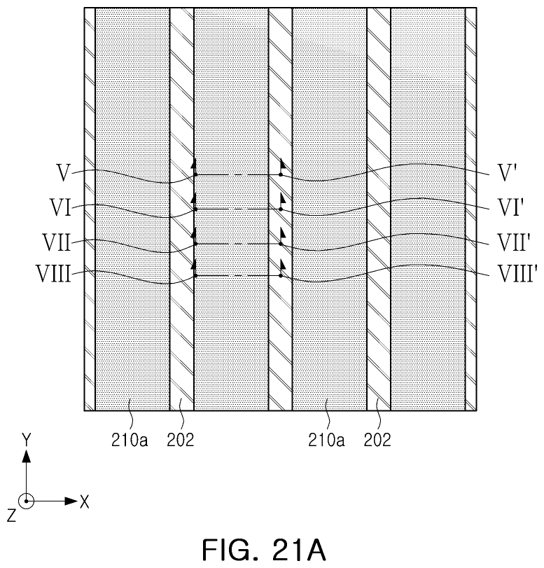

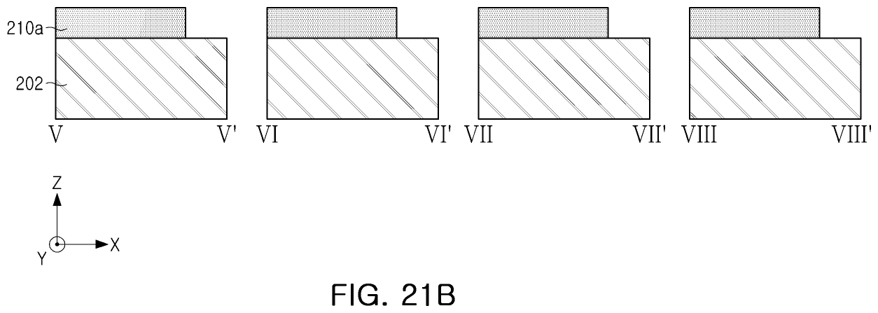

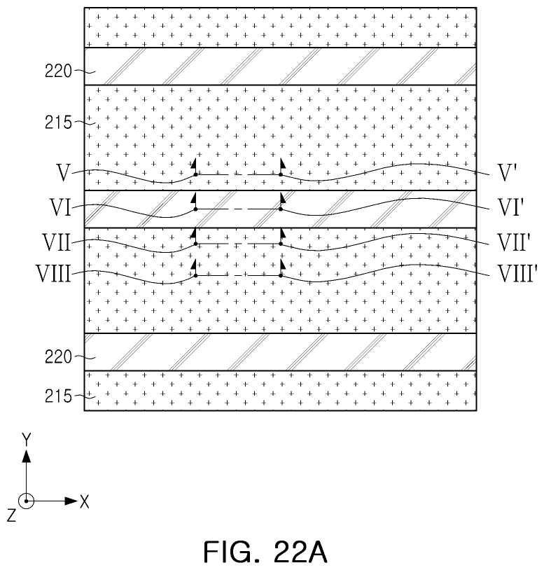

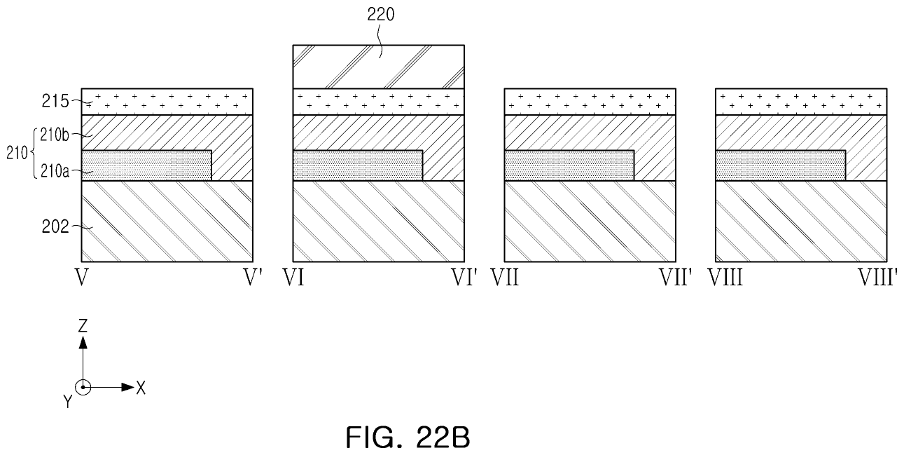

FIGS. 21A to 28B are plan views and vertical cross-sectional views shown according to a process sequence to illustrate a method of forming a semiconductor pattern according to an example embodiment.

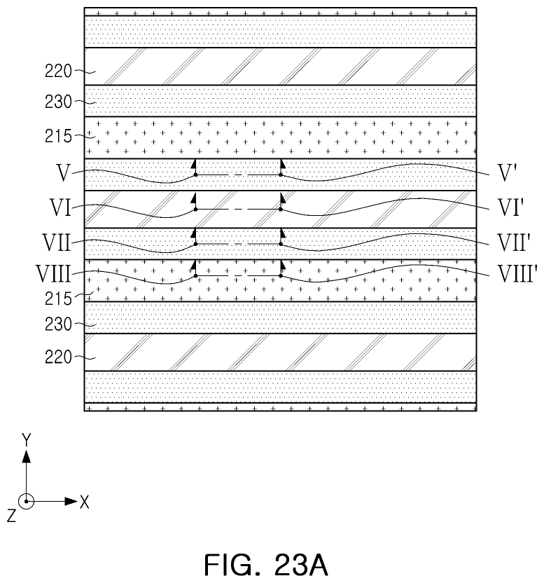

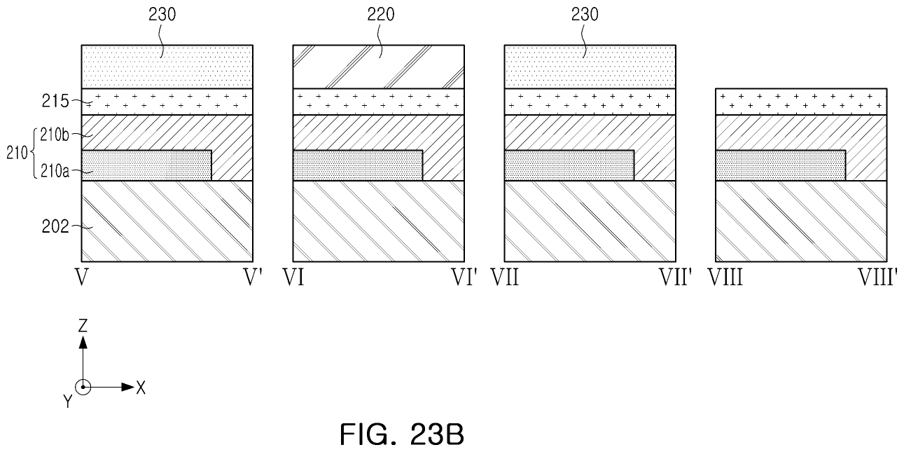

Specifically, FIGS. 23a, 24a, 25a, 26a, 27a, 28a and 29a are plan views, and FIGS. 23b, 24b, 25b, 26b, 27b, 28b and 29b are vertical cross-sectional views taken along lines V-V′, VI-VI, VII-VII′ and VIII-VIII′ of FIG. 14B.

Referring to FIG. 1B and FIGS. 21A to 22B, an insulating layer such as a molded layer 210 may be formed on a substrate 202 (S110). Forming the molded layer 210 (S110) may include forming a first, lower insulating layer such as a lower molded layer 210a on the substrate 202, patterning the lower molded layer 210a, and forming a second, upper insulating layer such as an upper molded layer 210b on the lower molded layer 210a. The lower molded layer 210a and the upper molded layer 210b may form the molded layer 210.

The substrate 202 may correspond to substrate 102 in FIG. 12A and substrate 3 in FIG. 14A. The lower molded layers 210a may extend in the Y-direction, and may be spaced apart from each other in the X-direction. The lower molded layers 210a may include silicon oxide. The lower molded layers 210a may be formed by stacking a silicon oxide layer on the substrate 202, or by oxidizing an upper surface of the substrate 202. The upper molded layer 210b may cover the substrate 202 and the lower molded layers 210a. The upper molded layer 210b may include an amorphous carbon layer (ACL).

An anti-reflection layer 215 may be formed on the upper molded layer 210b. The anti-reflection layer 215 may include silicon nitride, silicon oxynitride, or a combination thereof.

Mask patterns 220 may be formed on the anti-reflection layer 215 on the molded layer 210 (S120). The mask patterns 220 may extend in the X-direction, and may be spaced apart from each other in the Y-direction. The mask patterns 220 may include polysilicon.

Referring to FIGS. 1B, 23A, and 23B, spacer layers 230 may be formed on side surfaces of the mask patterns 220 (S130). In an example embodiment, the spacer layers 230 may be formed on the side surfaces of the mask patterns 220 in a self-aligned manner. For example, the spacer layers 230 may be formed by depositing a spacer material layer to cover the anti-reflection layer 215 and the mask patterns 220 and anisotropically etching the spacer material layer.

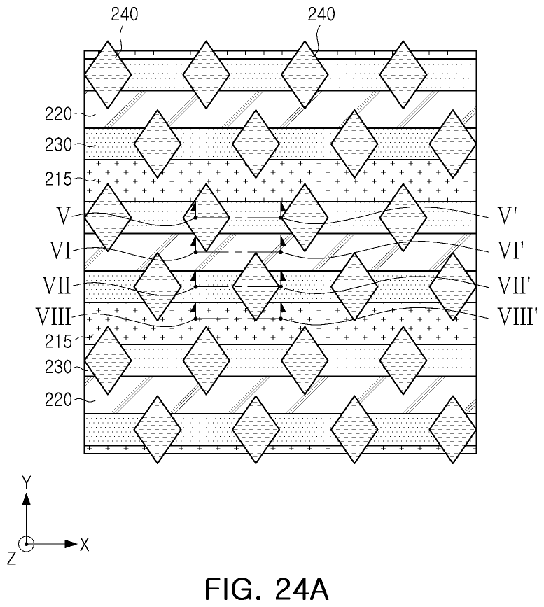

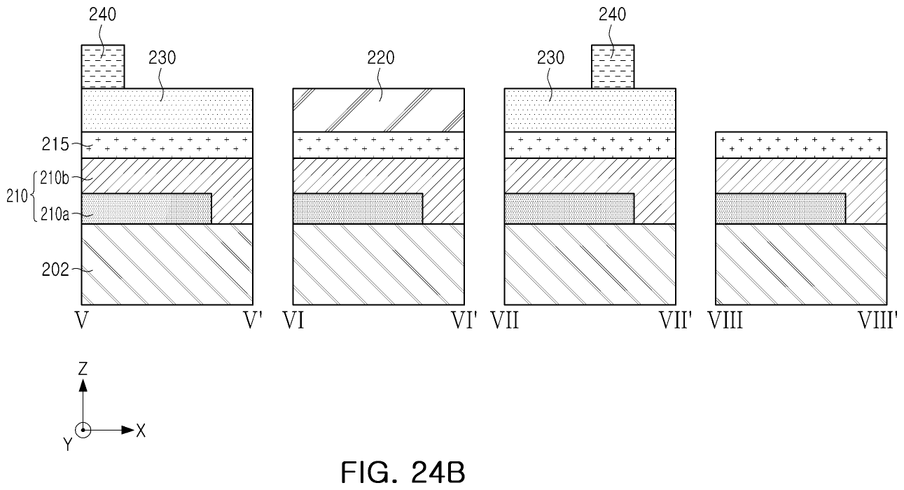

Referring to FIGS. 24A and 24B, a photoresist 240 may be formed on the spacer layers 230. The photoresist 240 may be formed by forming a photosensitive material to cover the anti-reflection layer 215, the mask patterns 220, and the spacer layers 230, and patterning the photosensitive material. In an example embodiment, a horizontal dimension, e.g., width, of the photoresist 240 in the Y-direction may be greater than a horizontal dimension, e.g., width, of the spacer layers 230 in the Y-direction. For example, the photoresist 240 may vertically overlap the anti-reflection layer 215 and the mask patterns 220.

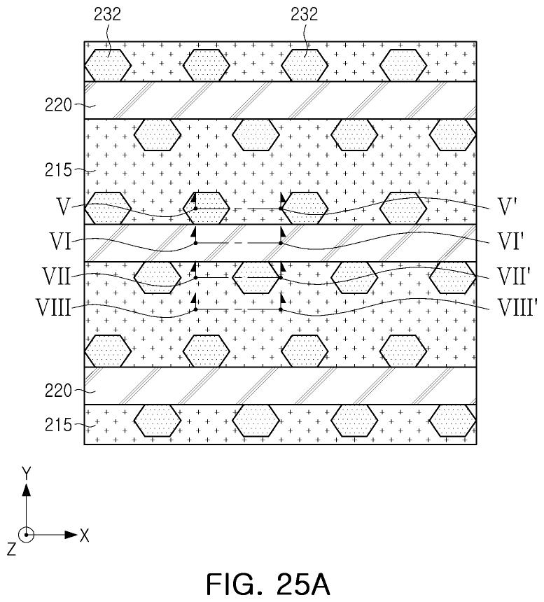

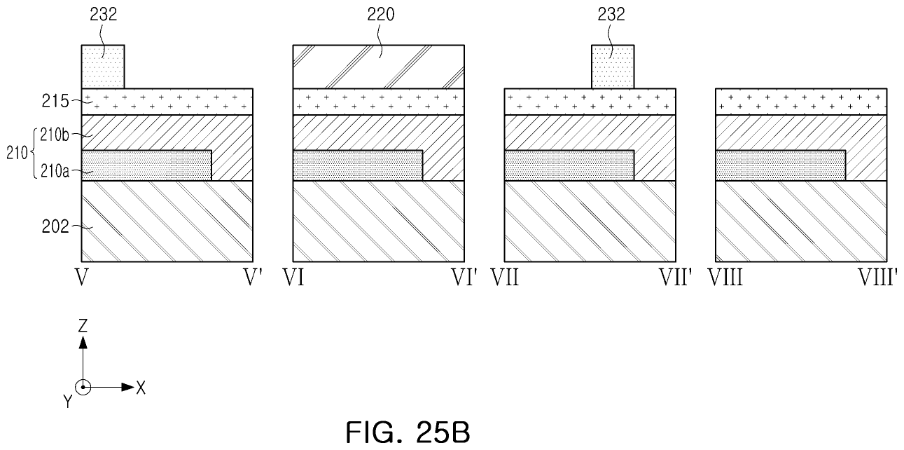

Referring to FIGS. 1B, 25A, and 25B, spacer patterns 232 may be formed by patterning the spacer layers 230 (S140). Forming the spacer patterns 232 (S140) may include anisotropically etching the spacer layers 230 using the photoresist 240 as an etching mask. For example, among the spacer layers 230 shown in FIG. 25A, a portion vertically overlapping the photoresist 240 may remain to form spacer patterns 232. The anti-reflection layer 215 and the mask patterns 220 may have etch selectivity with the spacer layers 230 and may not be etched by the etching process. Since the anti-reflection layer 215 and the mask patterns 220 are not etched and the spacer layers 230 are selectively etched, even though a width of the photoresist 240 in the Y-direction is greater than a width of the spacer layers 230 in the Y-direction, a width of the spacer patterns 232 in the Y-direction may be limited to be less than or equal to the width of the spacer layers 230 in the Y-direction. That is, the width of the spacer patterns 232 in the Y-direction may be formed to be constant, and process variations can be reduced.

In plan view, the spacer patterns 232 are shown as having a hexagonal shape, but the present inventive concept is not limited thereto. In some example embodiments, the side surfaces of the spacer patterns 232 may be rounded and may have shapes such as circular, oval, and the like. The mask patterns 220 may correspond to a body portion 207 of a semiconductor pattern 206, to be described later. The spacer patterns 232 may correspond to a first head portion 208 and a second head portion 209 of the semiconductor pattern 206, to be described later.

Referring to FIGS. 1B and 26A to 27B, a mold pattern 212 may be formed by etching the molded layer 210 using the mask patterns 220 and the spacer patterns 232 as an etching mask (S150). Forming the mold pattern 212 by etching the molded layer 210 may include etching an upper molded layer 210b using the spacer patterns 232 as an etching mask, and etching a lower molded layer 210a using the upper molded layer 210b as an etching mask.

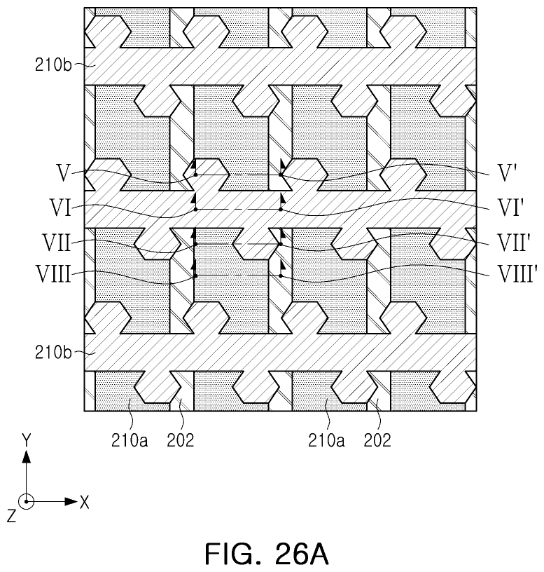

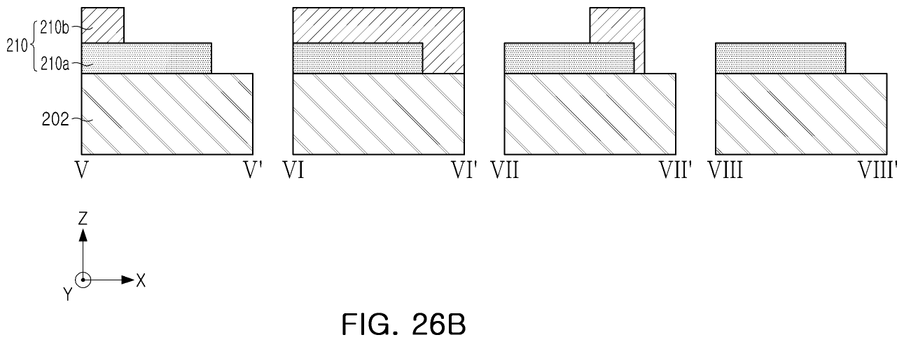

As shown in FIGS. 26A and 26B, an upper molded layer 210b may be etched using the mask patterns 220 and the spacer patterns 232 as an etching mask. The upper molded layer 210b may extend in the X-direction and may include protrusions protruding in the Y-direction at positions corresponding to the spacer patterns 232. In plan view, the protrusions are shown as having a hexagonal shape, but the present inventive concept is not limited thereto. In some example embodiments, the protrusions may be rounded.

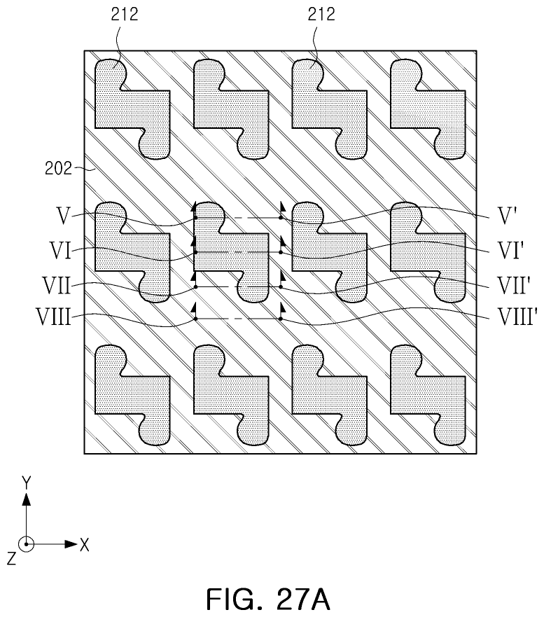

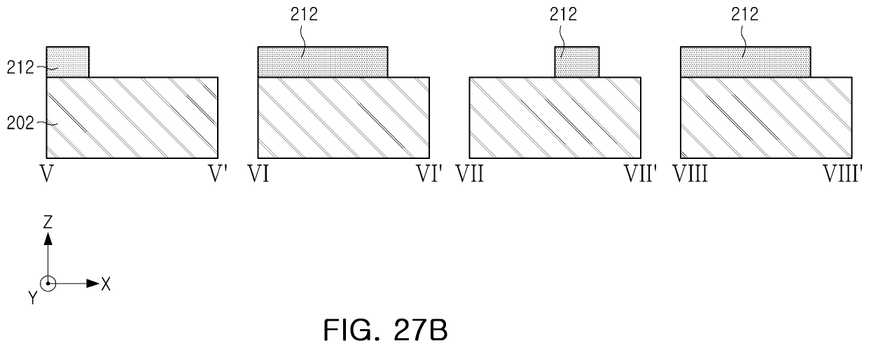

As shown in FIGS. 27A and 27B, the lower molded layer 210a may be etched using the upper molded layer 210b as an etching mask to form a mold pattern 212. For example, a mold pattern 212 may be formed by leaving a portion of the lower molded layer 210a shown in FIG. 26A vertically overlapping the upper molded layer 210b. A width of the mold pattern 212 in the X-direction may be limited to be less than or equal to a width of the lower molded layer 210a in the X-direction. Accordingly, a width of a semiconductor pattern 206, which will be described later, in the X-direction may be formed to be constant, and process variations can be reduced.

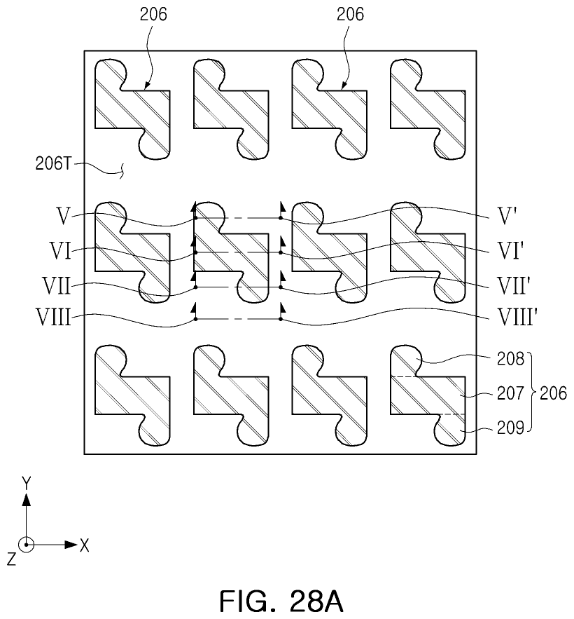

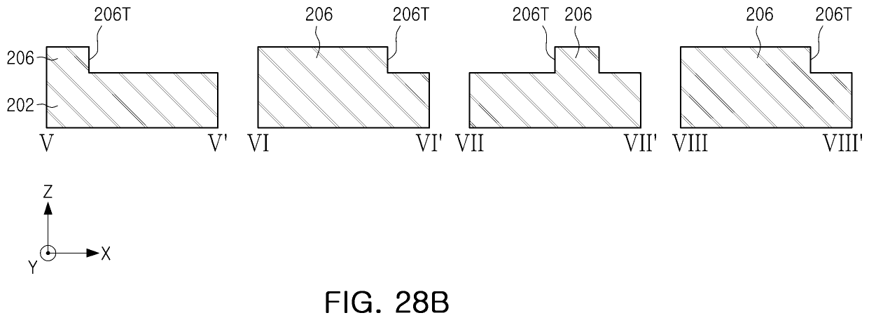

Referring to FIGS. 1B, 28A, and 28B, semiconductor patterns 206 and device isolation trenches 206T may be formed by etching the substrate 202 using the mold pattern 212 as an etching mask (S160). The device isolation trenches 206T may be formed on the upper surface of the substrate 202 and may define semiconductor patterns 206.

When viewed in plan view, the semiconductor pattern 206 may include a body portion 207 and a first head portion 208 and a second head portion 209 disposed at both ends of the body portion 207. The first head portion 208 and the second head portion 209 may be disposed symmetrically with respect to a center of the body portion 207. The body portion 207, the first head portion 208, and the second head portion 209 may correspond to the body portion 107, the first head portion 108, and the second head portion 109 shown in FIG. 13. The active regions 6a may be spaced apart from each other in the X and Y directions. For example, the body portions 7 of the active regions 6a may be spaced apart in a grid structure with regular intervals in the X and Y directions, respectively.

Thereafter, the semiconductor device 100 may be manufactured by performing a process identical or similar to the process described with reference to FIGS. 14A to 20B.

As set forth above, according to example embodiments of the technical idea of the present inventive concept, since spacer layers are formed on a side surface of a mask pattern in a self-aligned manner, process variations may be reduced when a semiconductor pattern is formed.

The various and advantageous advantages and effects of the present inventive concept are not limited to the above description, and may be more easily understood in the course of describing the specific embodiments of the present inventive concept.

While example embodiments have been shown and described above, it will be apparent to those skilled in the art that modifications and variations could be made without departing from the scope of the present invention as defined by the appended claims.

What is claimed is:

1. A method of manufacturing a semiconductor device, comprising:
forming an insulating layer on a substrate;
forming mask patterns on the insulating layer, the mask patterns extending in a first horizontal direction and spaced apart from each other in a second horizontal direction intersecting the first horizontal direction;
forming spacer layers on side surfaces of the mask patterns, wherein the spacer layers are spaced apart from each other in the second horizontal direction with each of the mask patterns interposed therebetween;
forming spacer patterns spaced apart from each other in the first horizontal direction on the side surfaces of the mask patterns by patterning the spacer layers;
forming mold patterns by etching the insulating layer using the mask patterns and the spacer patterns as an etching mask; and
forming a device isolation trench defining semiconductor patterns by etching the substrate using the mold patterns as an etching mask.

2. The method of manufacturing a semiconductor device of claim 1, wherein the spacer layers are formed on the side surfaces of the mask patterns in a self-aligned manner.

3. The method of manufacturing a semiconductor device of claim 1, wherein forming the spacer patterns comprises:
forming sacrificial patterns extending in a third horizontal direction and intersecting the mask patterns and the spacer layers;
forming sacrificial spacers, spaced apart from each other in the first horizontal direction, on side surfaces of the sacrificial patterns; and
etching the spacer layers using the sacrificial patterns and the sacrificial spacers as an etching mask.

4. The method of manufacturing a semiconductor device of claim 3, wherein the sacrificial spacers are formed on the side surfaces of the sacrificial patterns in a self-aligned manner.

5. The method of manufacturing a semiconductor device of claim 3, further comprising:
forming a first hard mask layer covering the mask patterns and the spacer layers before forming the sacrificial patterns,
wherein the sacrificial patterns vertically penetrate the first hard mask layer, and
wherein the sacrificial spacers are formed on the first hard mask layer.

6. The method of manufacturing a semiconductor device of claim 3, further comprising:
removing portions of the spacer patterns, before forming the mold patterns.

7. The method of manufacturing a semiconductor device of claim 6, wherein removing the portions of the spacer patterns comprises:
forming a second hard mask layer extending in a fourth horizontal direction, intersecting the third horizontal direction and covering the spacer patterns and the sacrificial patterns; and
etching the spacer patterns and the sacrificial patterns using the second hard mask layer as an etching mask.

8. The method of manufacturing a semiconductor device of claim 1, wherein:
each of the semiconductor patterns comprises a body portion extending in the first horizontal direction, and a first head portion and a second head portion respectively on side surfaces of opposite ends of the body portion, and
the body portion corresponds to one of the mask patterns, and each of the first head portion and the second head portion corresponds to a respective one of the spacer patterns.

9. The method of manufacturing a semiconductor device of claim 8, wherein each of the semiconductor patterns comprises a first side surface, perpendicular to the second horizontal direction and a second side surface opposite to the first side surface, and the first head portion is on the first side surface and the second head portion is on the second side surface.

10. The method of manufacturing a semiconductor device of claim 9, wherein the body portion comprises a third side surface, coplanar with a side surface of the first head portion and a fourth side surface, opposite to the third side surface and coplanar with a side surface of the second head portion.

11. The method of manufacturing a semiconductor device of claim 1, wherein the insulating layer comprises a lower insulating layer and an upper insulating layer on the lower insulating layer.

12. The method of manufacturing a semiconductor device of claim 11, wherein forming the insulating layer comprises:
forming the lower insulating layer on the substrate;
patterning the lower insulating layer; and
forming the upper insulating layer on the lower insulating layer.

13. The method of manufacturing a semiconductor device of claim 11, wherein forming the spacer patterns comprises:
forming a photoresist on the spacer layers; and
etching the spacer layers using the photoresist as an etching mask.

14. The method of manufacturing a semiconductor device of claim 11, wherein forming the mold patterns comprises:
etching the upper insulating layer using the mask patterns and the spacer patterns as an etching mask, and
etching the lower insulating layer using the upper insulating layer as an etching mask.

15. A method of manufacturing a semiconductor device, comprising:
forming an insulating layer on a substrate;
forming a mask pattern extending in a first horizontal direction on the insulating layer;
forming a first spacer layer and a second spacer layer formed on side surfaces of the mask pattern in a self-aligned manner, wherein the first spacer layer and the second spacer layer extend in the first horizontal direction along the side surfaces of the mask pattern and are spaced apart from each other in a second horizontal direction, intersecting the first horizontal direction with the mask pattern interposed therebetween;
forming a first spacer pattern and a second spacer pattern on the side surfaces of the mask pattern by patterning the first spacer layer and the second spacer layer, wherein the first spacer pattern and the second spacer pattern are disposed symmetrically with respect to a center of the mask pattern;
forming a mold pattern by etching the insulating layer using the mask pattern, the first spacer pattern, and the second spacer pattern as an etching mask; and
forming a device isolation trench defining semiconductor patterns by etching the substrate using the mold pattern as an etching mask,
wherein each of the semiconductor patterns includes a body portion extending in the first horizontal direction, and a first head portion and a second head portion respectively on side surfaces of opposite ends of the body portion, and
wherein the body portion corresponds to the mask pattern, and each of the first head portion and the second head portion corresponds respectively to the first spacer pattern and the second spacer pattern.

16. The method of manufacturing a semiconductor device of claim 15, wherein each of the first head portion and the second head portion comprises a side surface, coplanar with a side surface of the body portion.

17. The method of manufacturing a semiconductor device of claim 16, wherein the body portion is at the same horizontal position as the mask pattern, and each of the first head portion and the second head portion is at the same horizontal position as the first spacer pattern and the second spacer pattern.

18. A method of manufacturing a semiconductor device, comprising:
forming semiconductor patterns including body portions, and first head portions and second head portions respectively disposed on side surfaces of opposite ends of the body portions;
forming gate structures intersecting the body portions of the semiconductor patterns;
forming bit line structures intersecting the gate structures; and
forming landing pads electrically connected to the semiconductor patterns on the bit line structures,
wherein forming the semiconductor patterns includes:
forming an insulating layer on a substrate;
forming mask patterns on the insulating layer, the mask patterns extending in a first horizontal direction and spaced apart from each other in a second horizontal direction intersecting the first horizontal direction;
forming spacer layers on side surfaces of the mask patterns, wherein the spacer layers are spaced apart from each other in the second horizontal direction with each of the mask patterns interposed therebetween;
forming spacer patterns spaced apart from each other in the first horizontal direction on the side surfaces of the mask patterns by patterning the spacer layers;
forming mold patterns by etching the insulating layer using the mask patterns and the spacer patterns as an etching mask; and
forming a device isolation trench defining the semiconductor patterns by etching the substrate by using the mold patterns as an etching mask.

19. The method of manufacturing a semiconductor device of claim 18, wherein the bit line structures vertically overlap the first head portions of the semiconductor patterns.

20. The method of manufacturing a semiconductor device of claim 18, wherein the landing pads vertically overlap the second head portions of the semiconductor patterns.
